(19) United States
(12) Patent Application Publication
(10) Pub. No.: US 2025/0294764 A1
(43) Pub. Date: Sep. 18, 2025

(54) TWO-DIMENSIONAL SEMICONDUCTOR MATERIAL-BASED CHARGE SUPER-INJECTION MEMORY AND PREPARATION THEREOF

(71) Applicant: Fudan University, Shanghai (CN)

(72) Inventors: Chunsen LIU, Shanghai (CN); Yutong XIANG, Shanghai (CN); Peng ZHOU, Shanghai (CN)

(21) Appl. No.: 19/222,935

(22) Filed: May 29, 2025

(30) Foreign Application Priority Data
Mar. 11, 2025 (CN) 202510281027.0

(51) Int. Cl. H10B 43/30; H10D 30/01; H10D 30/47; H10D 62/10; H10D 62/80; H10D 64/01; H10D 64/62; H10D 64/66; H10D 64/68

(52) U.S. Cl. CPC H10B 43/30; H10D 30/017; H10D 30/0413; H10D 30/481; H10D 62/102; H10D 62/883; H10D 64/037; H10D 64/62; H10D 64/665; H10D 64/685; H10D 64/691; H10D 64/693

(57) ABSTRACT

A two-dimensional semiconductor material-based charge super-injection memory, including a substrate, a gate electrode, a blocking layer, a charge-trapping layer, a tunneling layer, a two-dimensional semiconductor channel layer, a drain electrode and a source electrode. The gate electrode is provided above the substrate. The blocking layer is configured to cover the gate electrode and the substrate. The charge-trapping layer is provided on the blocking layer. The tunneling layer is provided on the charge-trapping layer. The two-dimensional semiconductor channel layer is provided on the tunneling layer. The two-dimensional semiconductor channel layer is entirely encompassed within a coverage area of the gate electrode and a coverage area of the tunneling layer. The drain electrode and the source electrode are each partially overlapped with the two-dimensional semiconductor channel layer. A fabrication method of such charge super-injection memory is also provided.

### CROSS-REFERENCE TO RELATED APPLICATIONS

This application claims the benefit of priority from Chinese Patent Application No. 202510281027.0, filed on Mar. 11, 2025. The content of the aforementioned application, including any intervening amendments thereto, is incorporated herein by reference in its entirety.

### TECHNICAL FIELD

This application relates to semiconductor memories, and more particularly to a two-dimensional semiconductor material-based charge super-injection memory and a preparation thereof.

### BACKGROUND

With the rapid development of artificial intelligence, the computing paradigm has been gradually transformed from traditional logical operations to data-driven computation. The existing hierarchical memory architecture struggles to meet the demand of computing chips for extremely high computing power and energy efficiency. In order to overcome the energy efficiency bottleneck under high computing power, there is an urgent need for non-volatile memory technology with sub-nanosecond operation speed. At present, the fastest static random-access memory (SRAM) can achieve a speed of less than 1 nanosecond. However, its data volatility results in high power consumption for data storage, and it is also limited by complex structure and low storage capacity. Compared with the volatile memory, the non-volatile memory can offer data retention for up to 10 years, with excellent power consumption and storage capacity. The commercially available non-volatile memories are dominated by flash memory, however, its programming speed lags far behind the volatile memory technology, which greatly limits its application in the high-speed storage scenario.

Considerable attempts have been made to break through the speed bottleneck of flash memory. It has been found that the speed of flash memory can be effectively increased through the hot electron injection mechanism, in which the carriers can be accelerated by the horizontal electric field in the channel to gain sufficient energy to cross the potential barrier between the channel and the tunneling layer to be injected into the charge-trapping layer. However, for the silicon material system, the acceleration efficiency offered by the horizontal electric field is limited, and thus it can only support a programming speed of tens of nanoseconds, and still fails to reach the sub-nanosecond programming speed.

Therefore, it is urgent to develop a novel working mechanism to realize efficient injection of electric charge in the flash memory, so as to implement the sub-nanosecond non-volatile programming operation.

### SUMMARY

In view of the problem in the prior art that the acceleration efficiency offered by a horizontal electric field in the existing flash memories is unsatisfactory, this application provides a two-dimensional (2D) semiconductor material-based charge super-injection memory, and a preparation thereof, so as to implement the sub-nanosecond non-volatile programming operation.

This application provides a charge super-injection memory based on a two-dimensional semiconductor material. Non-volatile storage characteristics of the flash memory are realized through design of storage stacked energy band. Through a design of the horizontal electric field and a simulation design of devices, atomic-scale thin-film properties of the two-dimensional semiconductor material are utilized, significantly enhancing a maximum horizontal electric field, which increases an injection efficiency of a charge and realizes super-injection mechanism of the charge in memory, so as to realize sub-nanosecond programming of the flash memory.

A charge super-injection memory based on a two-dimensional semiconductor material is provided, comprising:
a substrate;
a gate electrode;
a blocking layer;
a charge-trapping layer;
a tunneling layer;
a two-dimensional semiconductor channel layer;
a drain electrode; and
a source electrode;
wherein the gate electrode is provided above the substrate; the blocking layer is configured to cover the gate electrode and the substrate; the charge-trapping layer is provided on the blocking layer; the tunneling layer is provided above the charge-trapping layer; the two-dimensional semiconductor channel layer is provided on the tunneling layer; the two-dimensional semiconductor channel layer is entirely encompassed within a coverage area of the gate electrode, and is entirely encompassed within a coverage area of the tunneling layer; and the drain electrode and the source electrode each partially overlap with the two-dimensional semiconductor channel layer.

In an embodiment, the substrate is made of SiO₂ or Si₃N₄; and a thickness of the substrate is 100-1000 nm.

In an embodiment, the gate electrode is made of Pt or Au; and a thickness of the gate electrode 10-30 nm.

In an embodiment, the blocking layer is made of Al₂O₃ or ZrO₂; and a thickness of the blocking layer is 15-50 nm.

In an embodiment, the charge-trapping layer is made of HfO₂ or Si₃N₄; and a thickness of the charge-trapping layer is 1-10 nm.

In an embodiment, the tunneling layer is made of hBN or SrTiO₃; and a thickness of the tunneling layer is 5-15 nm.

In an embodiment, the two-dimensional semiconductor channel layer is made of WSe₂, MoSe₂ or ReSe₂; and a thickness of the two-dimensional semiconductor channel layer is less than 10 nm.

In an embodiment, the drain electrode and the source electrode are each independently made of Ti, Sb, Cr, Au or Pt; a thickness of the drain electrode is 10-100 nm; and a thickness of the source electrode is 10-100 nm.

A method for preparing the charge super-injection memory above, comprising:
(S1) patterning a rigid substrate with a thickness of 100-1000 nm; and depositing a first metal layer with a thickness of 10-30 nm on the rigid substrate followed by stripping to form the gate electrode;
(S2) subjecting the gate electrode to plasma processing; and sequentially growing the blocking layer and the charge-trapping layer through atomic layer deposition, wherein a thickness of the blocking layer is 15-50 nm, and a thickness of the charge-trapping layer is 1-10 nm;
(S3) harvesting a dielectric film with a thickness of 5-15 nm from a dielectric bulk material by mechanical exfoliation; transferring the dielectric film through dry transfer onto the rigid substrate to form the tunneling layer;
(S4) harvesting a two-dimensional semiconductor channel film with a thickness of less than 10 nm from a two-dimensional semiconductor bulk material by mechanical exfoliation; transferring the two-dimensional semiconductor channel film through dry transfer to the rigid substrate such that the two-dimensional semiconductor channel film is entirely encompassed within the coverage area of the gate electrode and the coverage area of the tunneling layer, so as to form the two-dimensional semiconductor channel layer; performing an annealing treatment to enhance adhesion between the two-dimensional semiconductor channel layer and the tunneling layer; and
(S5) defining the source electrode and the drain electrode by photolithography patterning; and depositing a second metal layer with a thickness of 10-100 nm, followed by exfoliation to form the drain electrode and the source electrode.

The present disclosure prepares the charge super-injection memory based on the two-dimensional semiconductor material. With the development of charge super-injection mechanism, the atomic-scale thin-film properties of the two-dimensional semiconductor material are utilized to optimize the horizontal electric field, which significantly increases charge acceleration and injection efficiency, so that the memory realizes sub-nanosecond programming under the premise of maintaining the non-volatile storage characteristics, providing a new idea for solving a major challenge of high speed and non-volatility in the field of charge storage.

### BRIEF DESCRIPTION OF THE DRAWINGS

FIG. 1 shows a structure of a charge super-injection memory based on a two-dimensional semiconductor material according to an embodiment of the present disclosure.

FIG. 2 is a flow chart of a preparation method for the charge super-injection memory based on the two-dimensional semiconductor material according to an embodiment of the present disclosure.

FIG. 3 shows a storage stacked energy band of the charge super-injection memory based on the two-dimensional semiconductor material according to an embodiment of the present disclosure.

FIG. 4a shows a channel pinch-off schematic diagram of the charge super-injection memory based on the two-dimensional semiconductor material according to an embodiment of the present disclosure.

FIG. 4b is a design diagram of a horizontal electric field of the charge super-injection memory based on the two-dimensional semiconductor material according to an embodiment of the present disclosure.

FIG. 5 shows a relationship between a maximum horizontal electric field strength and a channel thickness in an analogue simulation of the charge super-injection memory based on the two-dimensional semiconductor material according to an embodiment of the present disclosure.

### DETAILED DESCRIPTION OF EMBODIMENTS

The present disclosure will be further described below with reference to the embodiments.

It should be noted that the terms, such as “up”, “down”, “vertical”, “horizontal” and other directional indications used herein, are only used for illustrating relative position relationship and motion between components in a specific state (as shown in the accompanying drawings), rather than limiting the disclosure.

In addition, details, such as structures, materials, sizes and processing technologies of devices can be implemented without following these specific details for facilitating understanding for those ordinary in the art. Unless otherwise specified, various components in the devices can be composed of materials known to those skilled in the art, or materials with similar functions to be developed in the future.

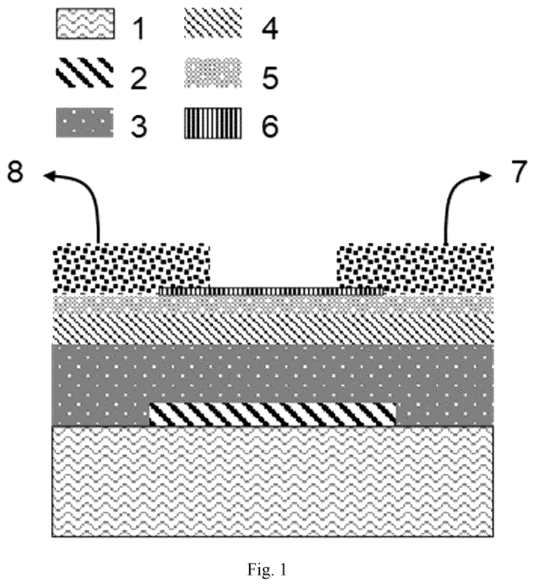

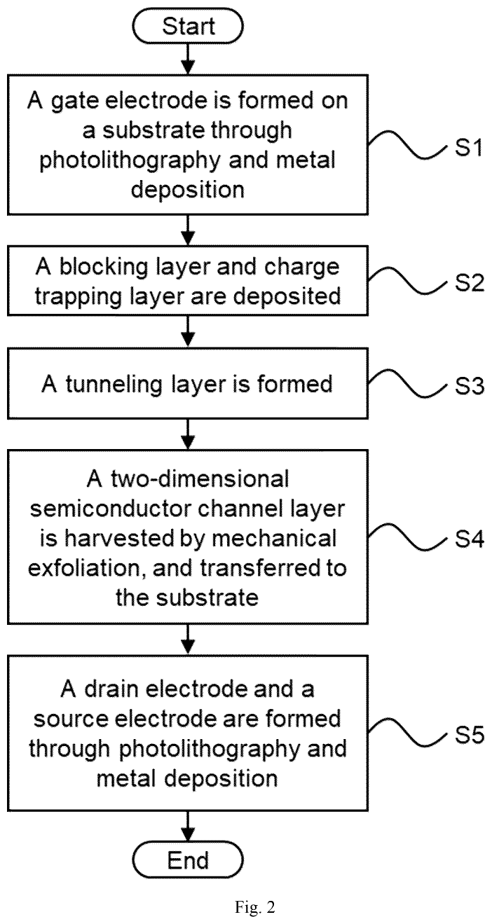

FIG. 1 shows a structure of a charge super-injection memory based on a two-dimensional semiconductor material. Referring to FIG. 2, a method for preparing the charge super-injection memory based on the two-dimensional semiconductor material includes the following steps.

(S1) A substrate 1 with 300 nm of SiO₂ grown in heavily doped p-type silicon is selected. The substrate 1 is patterned by a photolithographically patterned bottom-gate electrode for developing to obtain a first positive photoresist pattern, followed by deposition of a Cr/Au metal thin layer, where a thickness of Cr in the Cr/Au metal thin layer is 5 nm, and a thickness of Au in the Cr/Au metal thin layer is 10 nm. The first positive photoresist pattern is exfoliated in an acetone solution to form a gate electrode 2.

(S2) The gate electrode 2 is subjected to an oxygen plasma treatment at 50 W for 20 s. An Al₂O₃ thin film with high κ dielectric and a HfO₂ thin film with high K dielectric is prepared through atomic layer deposition at 250° C., where a deposition thickness of the Al₂O₃ thin film is 20 nm, and a deposition thickness of the HfO₂ thin film is 3 nm; the Al₂O₃ thin film is used as a blocking layer 3, and the HfO₂ thin film is used as a charge-trapping layer 4.

(S3) A hBN thin film is harvested from the two-dimensional semiconductor material by mechanical exfoliation. The hBN thin film is transferred by polydimethylsiloxane (PDMS) through dry transfer onto the substrate 1 to form a tunneling layer 5.

(S4) A WSe₂ thin film is harvested from the two-dimensional semiconductor material by mechanical exfoliation. The WSe₂ thin film is transferred by PDMS through dry transfer onto a target position to form a two-dimensional semiconductor channel layer 6, followed by an annealing treatment at 200° C. for 2 h, where it should be noted that the two-dimensional semiconductor channel layer 6 needs to be entirely encompassed within a coverage area of the gate electrode 2 and a coverage area of the tunneling layer 5.

(S5) A source electrode and a drain electrode are defined by photolithography patterning to develop to obtain a second positive photoresist pattern, followed by deposition of a Sb/Pt metal thin layer, where a thickness of Sb in the Sb/Pt metal thin layer is 5 nm, and a thickness of Pt in the Sb/Pt metal thin layer is 12 nm. The second positive photoresist pattern is exfoliated in the acetone solution to form a drain electrode 7 and a source electrode 8.

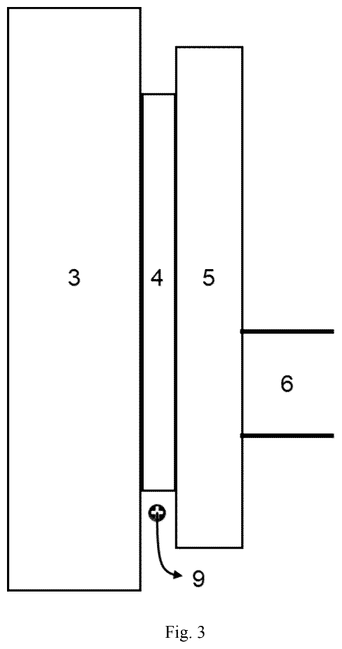

FIG. 3 shows a storage stacked energy band of the charge super-injection memory based on the two-dimensional semiconductor material. By selecting an appropriate band design and considering parameters, such as electronic affinities of the blocking layer, the charge-trapping layer and the tunneling layer, a band potential well is formed in the storage stacked energy band of the flash memory. Once a charge 9 is injected into the charge-trapping layer from a two-dimensional semiconductor channel to realize stable storage, it will not return to the two-dimensional semiconductor channel. The two-dimensional semiconductor channel is made of a material with a hole injection barrier that is smaller than electron injection barrier, therefore, the charge 9 is a hole. At the same time, by designing the thickness of the blocking layer and the tunneling layer, a coupling ratio of the gate electrode and prevention of injection of the gate electrode are taken into account.

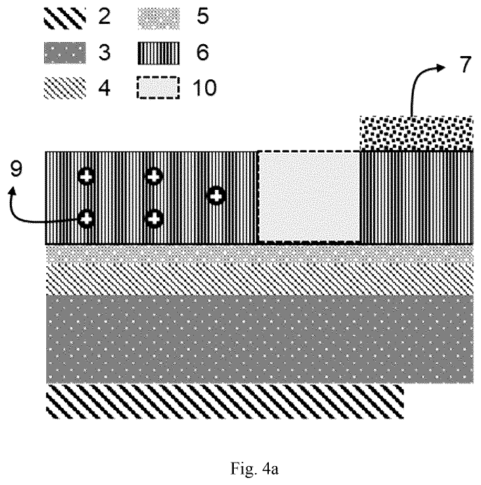

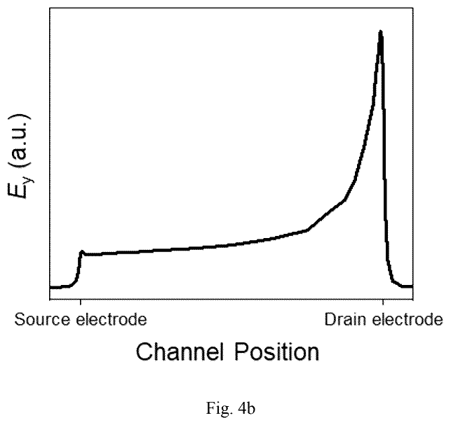

The present disclosure provides a control design of the charge super-injection memory based on the two-dimensional semiconductor. Referring to FIG. 4a, a specific horizontal electric field (E_{y}) is designed as follows. Taking a P-type two-dimensional semiconductor channel layer WSe₂ as an example, a negative programming voltage is applied to the gate electrode and the drain electrode with the source electrode grounded, ensuring an absolute value of a difference between a voltage of the gate electrode and a threshold voltage is smaller than an absolute value of a voltage of the drain electrode; and a pinch-off area 10 exists in the two-dimensional semiconductor channel, which is corresponding to a high resistance area where has no hole. Referring to FIG. 4b, for the whole two-dimensional semiconductor channel, the closer to a drain electrode, the greater the resistance, therefore, the horizontal electric field shows an upward trend from the source electrode to the drain electrode. Under such voltage condition, there are a large number of holes in the two-dimensional semiconductor channel, and a large number of holes continuously obtain energy through acceleration in the two-dimensional semiconductor channel under the action of the specific horizontal electric field. At this time, some high-energy holes have the chance to cross a hole potential barrier between the two-dimensional semiconductor channel and the tunneling layer, resulting in a change of the memory state. Because the charge injection is sensitive to a maximum horizontal electric field (E_{ymax}), therefore, the charge injection is concentrated in an area close to the drain electrode. In addition, the source electrode and the drain electrode each adopt a semimetal that can form an ohmic contact with the two-dimensional semiconductor channel layer. For the two-dimensional semiconductor channel layer WSe₂, the source electrode and the drain electrode can each be an Sb/Pt metal thin layer. The metal Sb alleviates the fermi level pinning effect and reduces contact resistance, so that a horizontal voltage entirely acts on the two-dimensional semiconductor channel, ensuring the charge has a maximum acceleration effect in the two-dimensional semiconductor channel.

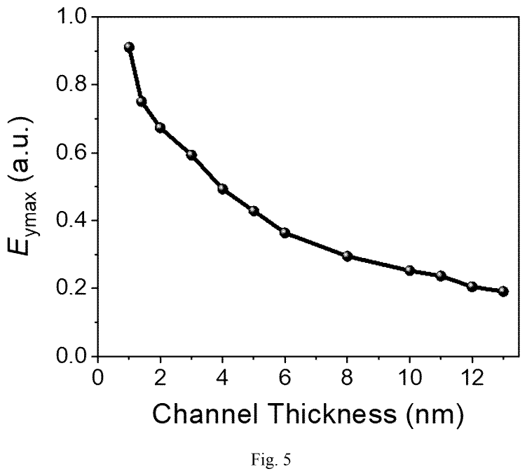

The present disclosure provides a functional verification of the charge super-injection memory based on the two-dimensional semiconductor. Referring to FIG. 5, a simulation design of a specific device is described as follows. A technology computer-aided design (TCAD) is used for device simulation. A drift-diffusion model is adopted to simulate a transport process of the charge in the two-dimensional semiconductor channel. A high-field velocity saturation model is configured to calculate the saturation velocity of the charge in a high field. A Shockley-Read-Hall composite model and an Auger composite model are adopted to describe a process of carrier recombination. A voltage condition in FIGS. 4a-b is adopted as a boundary condition, quantitative analysis is conducted by solving the Poisson's equation, a carrier continuity equation and a carrier transport equation, so as to quantify a change of the maximum horizontal electric field (E_{ymax}) in the charge super-injection memory under different channel thicknesses, showing a rule that the E_{ymax} increases as the thickness of the two-dimensional semiconductor channel decrease, which effectively improves charge injection efficiency. The functional verification shows E_{ymax} is maximized by utilizing a two-dimensional atomic-scale thin-film material, so as to realize efficient two-dimensional super-injection, which provides a theoretical basis for a design of super-injection memory.

A programming operation of the charge super-injection memory based on the two-dimensional semiconductor material is described as follows. Taking P-type two-dimensional semiconductor channel layer as an example, for the programming operation, a negative voltage pulse is applied on the gate electrode and the drain electrode, and the source electrode is kept grounded, so that a large number of holes are generated in the two-dimensional semiconductor channel. The large number of holes accelerate from the source electrode to the drain electrode, some high-energy holes, which have energy larger than the hole barrier between the two-dimensional semiconductor channel to the tunneling layer, have the chance to be injected to the charge-trapping layer, so as to realize the sub-nanosecond programming. At this time, after voltages applied on the gate electrode and the drain electrode are removed, the high-energy holes are trapped in the charge-trapping layer, so as to realize the non-volatile data storage.

Described above are only specific embodiments of this application, which are not intended to limit this application. For those skilled in the art, any changes and replacements that can easily thought shall fall within the scope of this application defined by the appended claims.

What is claimed is:

1. A two-dimensional semiconductor material-based charge super-injection memory, comprising:
a substrate;
a gate electrode;
a blocking layer;
a charge-trapping layer;
a tunneling layer;
a two-dimensional semiconductor channel layer;
a drain electrode; and
a source electrode;
wherein the gate electrode is provided above the substrate; the blocking layer is configured to cover the gate electrode and the substrate; the charge-trapping layer is provided on the blocking layer; the tunneling layer is provided above the charge-trapping layer; the two-dimensional semiconductor channel layer is provided on the tunneling layer; the two-dimensional semiconductor channel layer is entirely encompassed within a coverage area of the gate electrode, and is entirely encompassed within a coverage area of the tunneling layer; and the drain electrode and the source electrode each partially overlap with the two-dimensional semiconductor channel layer.

2. The charge super-injection memory of claim 1, wherein the substrate is made of SiO₂ or Si₃N₄; and a thickness of the substrate is 100-1000 nm.

3. The charge super-injection memory of claim 1, wherein the gate electrode is made of Pt or Au; and a thickness of the gate electrode 10-30 nm.

4. The charge super-injection memory of claim 1, wherein the blocking layer is made of Al₂O₃ or ZrO₂; and a thickness of the blocking layer is 15-50 nm.

5. The charge super-injection memory of claim 1, wherein the charge-trapping layer is made of HfO₂ or Si₃N₄; and a thickness of the charge-trapping layer is 1-10 nm.

6. The charge super-injection memory of claim 1, wherein the tunneling layer is made of hexagonal boron nitride (hBN) or SrTiO₃; and a thickness of the tunneling layer is 5-15 nm.

7. The charge super-injection memory of claim 1, wherein the two-dimensional semiconductor channel layer is made of WSe₂, MoSe₂ or ReSe₂; and a thickness of the two-dimensional semiconductor channel layer is less than 10 nm.

8. The charge super-injection memory of claim 1, wherein the drain electrode and the source electrode are each independently made of Ti, Sb, Cr, Au or Pt; a thickness of the drain electrode is 10-100 nm; and a thickness of the source electrode is 10-100 nm.

9. A method for preparing the charge super-injection memory of claim 1, comprising:
(S1) patterning a rigid substrate with a thickness of 100-1000 nm; and depositing a first metal layer with a thickness of 10-30 nm on the rigid substrate followed by lift-off to form the gate electrode;
(S2) subjecting the gate electrode to plasma processing; and sequentially growing the blocking layer and the charge-trapping layer through atomic layer deposition, wherein a thickness of the blocking layer is 15-50 nm, and a thickness of the charge-trapping layer is 1-10 nm;
(S3) harvesting a dielectric film with a thickness of 5-15 nm from a dielectric bulk material by mechanical exfoliation; transferring the dielectric film through dry transfer onto the rigid substrate to form the tunneling layer;
(S4) harvesting a two-dimensional semiconductor channel film with a thickness of less than 10 nm from a two-dimensional semiconductor bulk material by mechanical exfoliation; transferring the two-dimensional semiconductor channel film through dry transfer to the rigid substrate such that the two-dimensional semiconductor channel film is entirely encompassed within the coverage area of the gate electrode and the coverage area of the tunneling layer, so as to form the two-dimensional semiconductor channel layer; performing an annealing treatment to enhance adhesion between the two-dimensional semiconductor channel layer and the tunneling layer; and
(S5) defining the source electrode and the drain electrode by photolithography patterning; and depositing a second metal layer with a thickness of 10-100 nm, followed by lift-off to form the drain electrode and the source electrode.
